(19) United States
(12) Patent Application Publication
(10) Pub. No.: US 2004/0152247 A1
(43) Pub. Date: Aug. 5, 2004

(54) MOS transistor and fabrication method thereof

(75) Inventor: Kwan-Ju Koh, Seoul (KR)

Correspondence Address: PILLSBURY WINTHROP, LLP, P.O. BOX 10500, MCLEAN, VA, 22102, US

(73) Assignee: Anam Semiconductor Inc., Seoul (KR)

(21) Appl. No.: 10/747,113

(22) Filed: Dec. 30, 2003

(30) Foreign Application Priority Data
Jan. 30, 2003 (KR) 10-2003-0006412

(51) Int. Cl. H01L 21/336

(52) U.S. Cl. 438/197

(57) ABSTRACT

The present invention is directed to a MOS transistor and a fabrication method thereof, which is advantageous to small-sizing and is capable of securing stability of adjustment of threshold voltage. The method of fabricating the MOS transistor comprises the steps of: forming a protection insulation film, a first polysilicon layer and a protection oxide film in order on a semiconductor substrate defined as an active region of elements; selectively etching the protection oxide film and the first polysilicon layer such that the protection oxide film and the first polysilicon layer are left by a predetermined width corresponding to a desired width of a gate; forming source and drain regions by implanting impurity ions into the semiconductor substrate using the gate as a mask; forming a sacrificial oxide film on an entire top surface of the semiconductor substrate and then planarizing a top surface of the sacrificial oxide film by a chemical and mechanical polishing process until the first polysilicon layer is exposed; etching the exposed first polysilicon layer, the protection film, and the semiconductor substrate up to a predetermined depth such that a gate opening etched by the predetermined depth from a top surface of the semiconductor substrate is formed; implanting impurity ions into the semiconductor substrate exposed through the gate opening for adjustment of a threshold voltage; forming a gate oxide film on an inner wall of the gate opening and forming the gate by depositing a second polysilicon layer on the gate oxide film; and removing the sacrificial oxide film and the protection nitride film.

### BACKGROUND OF THE INVENTION

(a) Field of the Invention

The present invention relates to a semiconductor device, and more particularly to a MOS transistor and a method of fabricating the same.

(b) Description of the Related Art

In general, a conventional MOS transistor, which is a kind of field effect transistor (FET), includes source and drain regions formed on a semiconductor substrate, and a gate oxide film and a gate region formed on the semiconductor substrate having the source and drain regions formed thereon. In such a structure of the MOS transistor, metal wires for applying electrical signals to each of the source, drain, and gate regions, which serve as electrodes, to thereby operate the MOS transistor are connected to upper portions of the source, drain, and gate regions. Conventional techniques related to formation of an elevated gate in the MOS transistor are disclosed in U.S. Pat. Nos. 6,365,473, 6,346,447, and 6,117,712. FIG. 1 is a sectional view of the conventional MOS transistor. As shown in FIG. 1, a gate oxide film 2 with a predetermined width and a polysilicon 3 to be used as a gate electrode are formed on a surface of active region of a silicon wafer. Then, by injecting P or N-typed dopants of low concentration into the silicon wafer 1 at an element region using the polysilicon 3 as a mask, a lightly doped drain (LDD) 4 is formed on the silicon wafer 1 at the element region. Next, after side walls 5 are formed at both sides of the polysilicon 3, by injecting dopants of high concentration, which has the same conductivity as the LDD 4, into the silicon wafer 1 at the element region using the side walls 5 and the polysilicon 3, source and drain electrodes 5 are formed on the silicon wafer 1 at the element region.

The reason why the gate is made of the polysilicon 3 in the conventional MOS transistor having such a structure is that the polysilicon sufficiently satisfies conditions on properties of material, such as high melting point, easiness of film formation, easiness of line patterning, stability of oxidation atmosphere, and flat surface formation, required as the gate.

In addition, in an actual application to a MOS transistor device, the gate of polysilicon material is formed to have low resistance by containing dopants such as phosphorus, arsenic, and boron.

However, as the MOS transistor device becomes integrated higher and higher, there is a limit to realization of low resistance to be required for fine line width.

In addition, there is a difficulty in formation of ultra shallow junction to be required in a high integrated MOS transistor device.

Accordingly, there is a need of a MOS transistor with a new structure advantageous to small-sizing of devices and a fabrication method thereof.

In addition, in the conventional MOS transistor device, since a state of distribution of implanted dopants is changed through a thermal diffusion process for subsequent formation of source and drain, there is a problem of instability of threshold voltage of devices.

### SUMMARY OF THE INVENTION

In considerations of the above problem, it is an object of the present invention to provide a MOS transistor structure advantageous to small-sizing and a fabrication method thereof.

It is another object of the present invention to provide a method for securing stability of adjustment of threshold voltage in a MOS transistor device.

To achieve the above objects, there is provided a method for fabricating a MOS transistor device wherein a source and drain region is formed at a position higher than a position of a source and drain in a conventional MOS transistor device and then ions are implanted for adjusting a threshold voltage.

According to an aspect of the present invention, a method of fabricating a MOS transistor comprises the steps of: forming a protection insulation film, a first polysilicon layer and a protection oxide film in order on a semiconductor substrate defined as an active region of elements; selectively etching the protection oxide film and the first polysilicon layer such that the protection oxide film and the first polysilicon layer are left by a predetermined width corresponding to a desired width of a gate; forming source and drain regions by implanting impurity ions into the semiconductor substrate using the gate as a mask; forming a sacrificial oxide film on an entire top surface of the semiconductor substrate and then planarizing a top surface of the sacrificial oxide film by a chemical and mechanical polishing process until the first polysilicon layer is exposed; etching the exposed first polysilicon layer, the protection film, and the semiconductor substrate up to a predetermined depth such that a gate opening etched by the predetermined depth from a top surface of the semiconductor substrate is formed; implanting impurity ions into the semiconductor substrate exposed through the gate opening for adjustment of a threshold voltage; forming a gate oxide film on an inner wall of the gate opening and forming the gate by depositing a second polysilicon layer on the gate oxide film; and removing the sacrificial oxide film and the protection nitride film.

### BRIEF DESCRIPTION OF THE DRAWINGS

The accompanying drawings, which are incorporated in and constitute a part of the specification, illustrate an embodiment of the invention, and, together with the description, serve to explain the principles of the invention:

FIG. 1 is a sectional view of a conventional MOS transistor; and

FIGS. 2a to 2g are sectional views for illustrating a method for fabricating a MOS transistor according to the present invention.

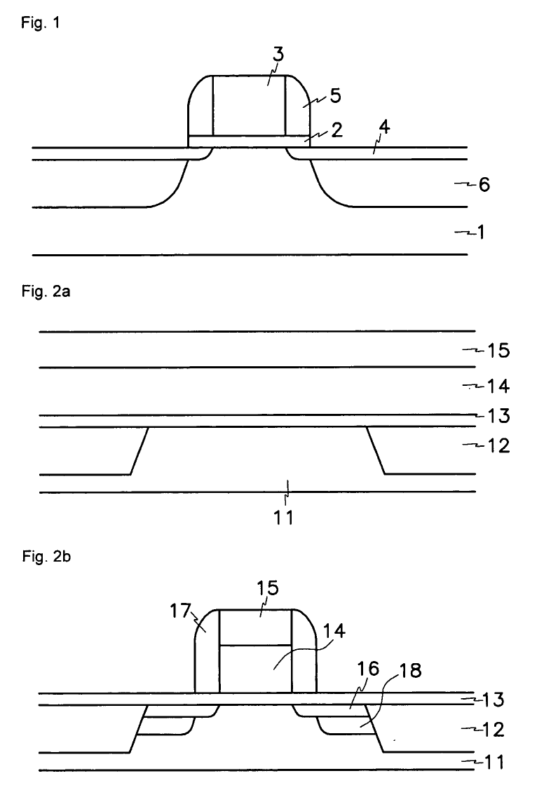

### DETAILED DESCRIPTION OF THE PREFERRED EMBODIMENT

A MOS transistor and a method for fabricating the same according to the present invention will now be described in detail with reference to the accompanying drawings.

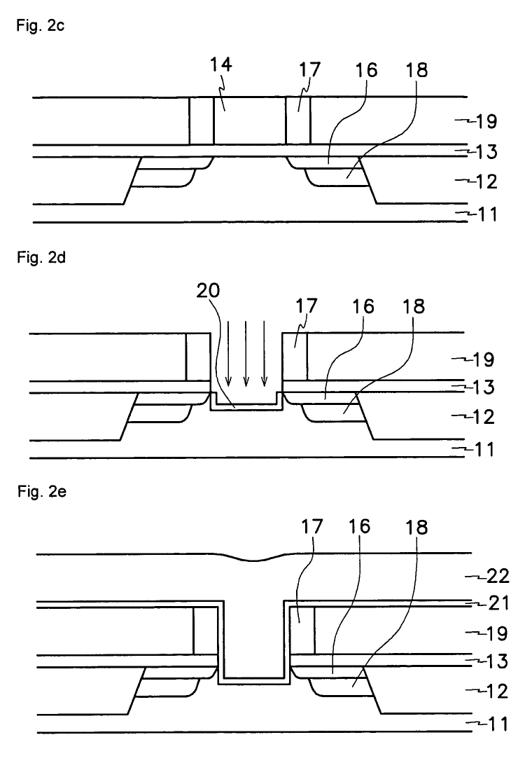

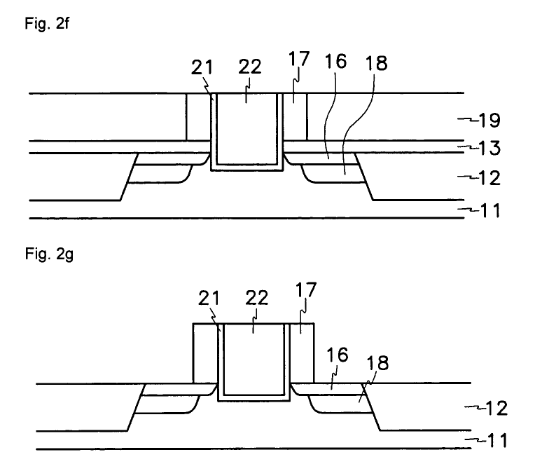

FIG. 2g shows a sectional view of a MOS transistor according to the present invention. As shown in this figure, a gate opening of a predetermined width etched up to a predetermined depth from a top surface of a semiconductor substrate 11 is formed and a gate 22 is formed at a predetermined height on the gate opening.

At this time, a gate oxide film 21 is preferable to be formed under the gate 22 and a side wall consisting of a nitride film is formed on a side surface of the gate oxide film 21.

The gate opening is preferable to be formed by being etched at a depth of 200-1,000 Å from the top surface of the semiconductor 11.

An LDD region 16 and a source and drain region 18 in which impurities are implanted are formed in the semiconductor substrate 11 outside the gate opening. Here, the LDD region 16 and the source and drain region 18 are located at a position higher than the bottom of the gate 22.

Now, a method for fabricating the MOS transistor having the above structure according to the present invention will be described with reference to FIGS. 2a to 2g.

First, as shown in FIG. 2a, a trench is formed by selectively etching a predetermined region of a silicon wafer 11, a field oxide film 12 is formed by filling the trench with an oxide film, and a region of the silicon wafer 11 except for the field oxide film is defined as an active region of element.

Subsequently, a protection nitride film 13, a first polysilicon layer 14 and a protection oxide layer 15 are formed in order on an entire top surface including the field oxide 12.

Next, as shown in FIG. 2b, the protection oxide film 15 and the first polysilicon layer 14 are selectively etched such that the protection oxide film and the first polysilicon layer are left by a predetermined width corresponding to a desired width of a gate, and then an LDD region 16 is formed by implanting impurity ions into the silicon wafer 11 at a low concentration using the protection oxide 15 and the first polysilicon layer 14 of the predetermined width as a mask.

Subsequently, a nitride film is formed on an entire top surface of the silicon surface 11 including the protection oxide film 15, a side wall 17 consisting of a nitride film is formed by vertically etching the nitride film such that the nitride film is left on side 0.20 surfaces of the protection oxide film 15 and the first polysilicon layer 14 until the protection film 15 is exposed.

Next, using the protection oxide film 15 and the side wall 17 as a mask, a source and drain region 18 is formed by implanting impurity ions into the silicon wafer 11 at a high concentration.

Next, as shown in FIG. 2c, a sacrificial oxide film 19 is deposited on an entire top surface of the silicon wafer 11, and then the protection film 15 is completely removed by chemically and mechanically polishing the protection oxide film 15 and the side wall 17 until the first polysilicon layer 14 is exposed.

At this time, it is preferable that the chemical and mechanical polishing is performed until the sacrificial oxide film 19 is removed by a predetermined thickness for complete removal of the protection oxide film 15.

Next, as shown in FIG. 2d, the first polysilicon layer 14 and the protection nitride 13 under the first polysilicon layer 14 are removed by a wet or dry etching process. At this time, a gate opening is formed by etching the silicon wafer 11 up to a predetermined thickness.

Namely, when the etching process is performed, the first polysilicon layer 14 is completely removed and then the gate opening is formed by etching the silicon wafer 11 under the first polysilicon layer 14 by a 200-1,000 Å more.

Subsequently, a thermal oxide film 20 having a 50-150 Å is grown on the silicon wafer 11 exposed through the gate opening by performing a thermal oxidation process at a temperature of 600-800° C., and then implantation of ions into the silicon wafer 11 is performed for adjusting a threshold voltage.

At this time, the reason why the thermal oxide film 20 is grown is to recover etching damage caused at the time of etching of the silicon substrate and prevent damage of the silicon substrate when the ions are implanted for the adjustment of the threshold voltage is performed.

In addition, since a thermal diffusion process for formation of the source and drain region 18 has been completed before the ions are implanted for the adjustment of the threshold voltage is performed, there is a merit that distribution of dopants implanted for the adjustment of the threshold voltage is stable.

Next, as shown in FIG. 2e, the thermal oxide film 20 is completely removed by a wet etching process, a gate oxide film 21 is thinly deposited on an entire top surface of the side wall 17 and the sacrificial oxide film 19 including an inner wall of the gate opening, and then a second polysilicon layer 22 to function as the gate is formed on the gate oxide film 21.

Since the gate is formed at a position lower than the top surface of the silicon wafer 11, consequently, the source and drain region 18 exists at a position higher than a conventional position of the source and drain region.

Next, as shown in FIG. 2f, the second polysilicon layer is planarized by a chemical and mechanical polishing process until the side wall 17 and the sacrificial oxide film 19 are exposed.

Finally, as shown in FIG. 2g, the sacrificial oxide film 19 is completely removed by a wet etching process, and then the protection nitride film 13 is completely removed by a dry etching process to complete the MOS transistor of the present invention.

As described above, According to the present invention, since the source and drain region is formed at a position higher than a conventional position of the source and drain region, an ultra shallow junction to be required in high integration MOS transistors can be formed, and accordingly, MOS transistors to be small-sized with a trend of high integration of devices can be easily fabricated.

Particularly, there is an advantage in that microscopic devices so downsized as not to be accomplished by conventional techniques can be fabricated.

In addition, since ions are implanted for adjustment of a threshold voltage after a source and drain region is formed, there is a merit that distribution of dopants implanted for the adjustment of the threshold voltage is stable.

Although an preferred embodiment of the present invention has been described in detail hereinabove, it should be clearly understood that many variations and/or modifications of the basic inventive concepts herein taught which may appear to those skilled in the present art will still fall within the spirit and scope of the present invention, as defined in the appended claims.

What is claimed is:

1. A MOS transistor comprising:
a semiconductor substrate including a gate opening of a predetermined width etched by a predetermined depth from a top surface the semiconductor substrate;
a gate formed on the gate opening at a predetermined height; and
a source and drain region whose top surface exists in a position higher than the bottom of the gate and into which impurity ions are implanted, the source and drain region formed in the semiconductor substrate outside the gate opening.

2. The MOS transistor of claim 1, further comprising a gate oxide film formed under the gate.

3. The MOS transistor of claim 2, wherein the gate opening is formed by being etched by a depth of 200-1,000 Å from a top surface of the semiconductor substrate.

4. The MOS transistor of claim 1, further comprising:
a side wall formed on a side surface of the gate and consisting of a nitride film;
an LDD region where impurity ions are implanted at a low concentration into the semiconductor substrate outside the gate opening,
wherein the source and drain region is formed outside the side wall and the impurity ions are implanted at a concentration higher in the source and drain region than in the LDD.

5. The MOS transistor of claim 2, further comprising:
a side wall formed on a side surface of the gate and consisting of a nitride film;
an LDD region where impurity ions are implanted at a low concentration into the semiconductor substrate outside the gate opening,
wherein the source and drain region is formed outside the side wall and the impurity ions are implanted at a concentration higher in the source and drain region than in the LDD.

6. The MOS transistor of claim 3, further comprising:
a side wall formed on a side surface of the gate and consisting of a nitride film;
an LDD region where impurity ions are implanted at a low concentration into the semiconductor substrate outside the gate opening,
wherein the source and drain region is formed outside the side wall and the impurity ions are implanted at a concentration higher in the source and drain region than in the LDD.

7. A method of fabricating a MOS transistor comprises the steps of:
forming a protection insulation film, a first polysilicon layer and a protection oxide film in order on a semiconductor substrate defined as an active region of elements;
selectively etching the protection oxide film and the first polysilicon layer such that the protection oxide film and the first polysilicon layer are left by a predetermined width corresponding to a desired width of a gate;
forming source and drain regions by implanting impurity ions into the semiconductor substrate using the gate as a mask;
forming a sacrificial oxide film on an entire top surface of the semiconductor substrate and then planarizing a top surface of the sacrificial oxide film by a chemical and mechanical polishing process until the first polysilicon layer is exposed;
etching the exposed first polysilicon layer, the protection film, and the semiconductor substrate up to a predetermined depth such that a gate opening etched by the predetermined depth from a top surface of the semiconductor substrate is formed;
implanting impurity ions into the semiconductor substrate exposed through the gate opening for adjustment of a threshold voltage;
forming a gate oxide film on an inner wall of the gate opening and forming the gate by depositing a second polysilicon layer on the gate oxide film; and
removing the sacrificial oxide film and the protection nitride film.

8. The method of claim 7, wherein, when the impurity ions are implanted into the semiconductor using the gate as a mask, the LDD region is formed by implanting the impurity ions at a low concentration, and after a side wall is formed on side surfaces of the protection oxide film and the first polysilicon layer, the source and drain region is formed by implanting the impurity ions at a high concentration into the semiconductor substrate using the side wall and the gate as a mask.

9. The method of claim 8, wherein, in the step of planarizing a top surface of the sacrificial oxide film by the chemical and mechanical polishing process until the first polysilicon layer is exposed, the protection oxide film is completely removed by chemically and mechanically polishing the sacrificial oxide film until the first polysilicon layer is removed by a predetermined thickness.

10. The method of claim 9, wherein, in the step of forming the gate opening, the semiconductor substrate is etched by a depth of 200-1,000 Å from a top surface of the semiconductor substrate.

11. The method of claim 10, wherein, before the step of implanting impurity ions for adjustment of the threshold voltage, a thermal oxide film is thermally grown at a thickness of 50-100 Å into the semiconductor substrate exposed through the gate opening, and after the step of implanting impurity ions for adjustment of the threshold voltage, the thermal oxide film is removed by a wet etching process.

12. The method of claim 11, wherein, in the step of forming the gate oxide film and the gate, the gate oxide film is formed on entire top surfaces of the side wall and the sacrificial oxide film including an inner wall of the gate opening, and after a second polysilicon layer is deposited on the gate oxide film, the second polysilicon layer is chemically and mechanically polished until the sacrificial oxide film is exposed.

13. The method of claim 7, wherein the sacrificial oxide film is removed by a wet etching process and the protection nitride film is removed by a dry etching process.

14. The method of claim 8, wherein the sacrificial oxide film is removed by a wet etching process and the protection nitride film is removed by a dry etching process.

15. The method of claim 9, wherein the sacrificial oxide film is removed by a wet etching process and the protection nitride film is removed by a dry etching process.

16. The method of claim 10, wherein the sacrificial oxide film is removed by a wet etching process and the protection nitride film is removed by a dry etching process.

17. The method of claim 11, wherein the sacrificial oxide film is removed by a wet etching process and the protection nitride film is removed by a dry etching process.

18. The method of claim 12, wherein the sacrificial oxide film is removed by a wet etching process and the protection nitride film is removed by a dry etching process.
